(19) United States
(12) Patent Application Publication
(10) Pub. No.: US 2018/0025767 A1
(43) Pub. Date: Jan. 25, 2018

(54) METHOD AND SYSTEM FOR DETERMINING MARKET ESTIMATES WITH MARKET BASED MEASURES

(71) Applicant: Richard L. Sandor, Chicago, IL (US)

(72) Inventor: Richard L. Sandor, Chicago, IL (US)

(21) Appl. No.: 15/697,129

(22) Filed: Sep. 6, 2017

Related U.S. Application Data
(63) Continuation of application No. 13/570,390, filed on Aug. 9, 2012, now Pat. No. 8,987,693.
Application No. 13/570,390 is a continuation-in-part of application No. 13/091,902, filed on Apr. 21, 2011, now abandoned.

(51) Int. Cl. G11C 11/404; G11C 13/00; H01L 49/02; H01L 49/00

(52) U.S. Cl. CPC G11C 11/404; H01L 28/40; G11C 13/0007; H01L 49/003

(57) ABSTRACT

A method and system for determining market estimates with market based measures. Market estimates for a set of time periods are received from plural qualified institutions that have agreed to a pre-determined set of regulations to participate in establishing, conducting business and processing transactions based on calculated market term estimates. A set of market term estimates (e.g., LIBOR, interest rates, etc.) is calculated in real-time for each time period in the set of time periods. The calculated set of market term estimates is sent to qualified institutions. The qualified institutions are required to conduct business and make transactions based on the calculated set of market term estimates. The calculated set of market term estimates is created and used on both cloud communication networks and non-cloud communications networks.

### CROSS REFERENCE TO RELATED APPLICATIONS

This application is a continuation of application Ser. No. 13/570,930 filed Aug. 9, 2012, entitled “Method and System for Determining Market Estimates with Market Based Measures” which is a continuation-in-part of application Ser. No. 13/091,902 filed Apr. 21, 2011, entitled “An Automated Method and System for Creating Tradable Hedge Fund Indices”, all of which are hereby incorporated by reference in their entirety

### FIELD OF INVENTION

This invention relates to determining market estimates on a computer network. More specifically, it relates to a method and system for determining market estimates and other estimates with market based measures and non-market based measures on cloud computing networks and other computer networks.

### BACKGROUND OF THE INVENTION

About twenty years ago, traders and bankers who specialized in the fields of loan syndication and forward rate agreements required a index against which to price their deals. There were not enough trades for a market-based index, so the British Bankers' Association, with the backing of the Bank of England, created an alternative index, the London Interbank Offered Rate, based on an average of daily estimates from participating banks The London Interbank Offered Rate is now used for derivatives contracts, as well as many credit cards, corporate loans and mortgages around the world.

The London Interbank Offered Rate is the average interest rate estimated by leading banks in London that they would be charged if borrowing from other banks. It is usually abbreviated LIBOR or BBA LIBOR (for British Bankers' Association Libor) LIBOR is the primary benchmark, along with the Euribor, for short term interest rates around the world.

LIBOR rates are calculated for ten different currencies and 15 borrowing periods ranging from overnight to one year and are published daily at 11:30 am (London time). Many financial institutions, mortgage lenders and credit card agencies set their own rates relative to it. Trillions of dollars in derivatives and other financial products are tied to the LIBOR.

In 2012, the U.S. Department of Justice, as part of a criminal investigation revealed significant fraud and collusion by member banks connected to LIBOR rate submissions, leading to a LIBOR scandal. The criminal abuses being investigated included the possibility that financial traders were in direct communication with bankers before the LIBOR rates were set, allowing the traders an advantage in predicting that day's fixing. It was estimated that that for each basis point (0.01%) that LIBOR was moved, those traders involved could net about “a couple of million dollars.”

There are a number of problems associated with calculating LIBOR rates. One problem is when there is no immediate consequence to fraud, some bankers and traders will engage in fraud.

Another problem is that consequences of committing such frauds are few. Most banks suffer no real reputational costs, and few individual bankers or traders pay out-of-pocket fines or do jail time.

Another problem is that current methods of calculating LIBOR rates is that they are merely surveys. Each bank submits “estimates” of its borrowing rates to the British Bankers' Association, a private trade body. No bank is actually obligated to lend or borrow at those estimated rates. There is no immediate consequence for submitting false rates in the surveys for the LIBOR rates.

Thus, it is desirable to solve some of the problems associated with calculating LIBOR rates, interest rates, market indexes and other market based rates based on market estimates.

### SUMMARY OF THE INVENTION

In accordance with preferred embodiments of the present invention, some of the problems associated with some of the problems associated with calculating LIBOR rates and other market rates with cloud computing networks are overcome. A method and system for determining market measures with market based estimates on cloud computing networks and other computer networks is presented.

Market estimates for a set of time periods are received from plural qualified financial institutions that have agreed to a pre-determined set of regulations to participate in establishing, conducting business and processing transactions based on calculated market term estimates. Non-market estimates can also be used. A set of market term estimates (e.g., LIBOR, other interest rates, etc.) is calculated in real-time for each time period in the set of time periods. The calculated set of market term estimates is sent to qualified financial institutions. The qualified financial institutions are required to conduct business and make transactions based on the calculated set of market term estimates. The calculated set of market term estimates is created and used on both cloud communication networks and non-cloud communications networks.

The foregoing and other features and advantages of preferred embodiments of the present invention will be more readily apparent from the following detailed description. The detailed description proceeds with references to the accompanying drawings.

### BRIEF DESCRIPTION OF THE DRAWINGS

Preferred embodiments of the present invention are described with reference to the following drawings, wherein:

FIG. 1 is a block diagram illustrating an exemplary electronic information display system;

FIG. 2 is a block diagram illustrating an exemplary electronic information display system;

FIG. 3 is a block diagram illustrating an exemplary networking protocol stack;

FIG. 4 is block diagram illustrating an exemplary cloud communications network;

FIG. 5 is a block diagram illustrating an exemplary cloud storage object;

FIGS. 6A and 6B are flow diagram illustrating a method for determining market estimates with market based measures; and

FIGS. 7A, 7B and 7C are flow diagram illustrating a method for determining market estimates with market based measures on a cloud communications network.

### DETAILED DESCRIPTION OF THE INVENTION

### Exemplary Cloud Market Estimate System

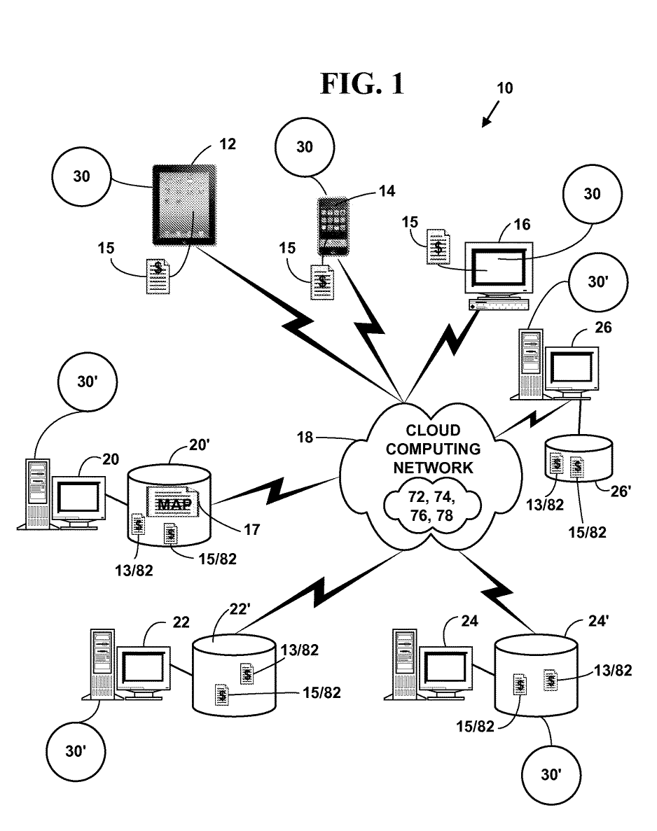

FIG. 1 is a block diagram illustrating an exemplary market estimate information system 10. The exemplary market estimate information system 10 includes, but is not limited to, one or more target network devices 12, 14, 16 (only three of which are illustrated) each with one or more processors and each with a non-transitory computer readable medium.

The one or more target network devices 12, 14, 16 include, but are not limited to, multimedia capable desktop and laptop computers, tablet computers, facsimile machines, mobile phones, non-mobile phones, smart phones, Internet phones, Internet appliances, personal digital/data assistants (PDA), two-way pagers, digital cameras, portable game consoles (Play Station Portable by Sony, Game Boy by Sony, Nintendo DSI, etc.), non-portable game consoles (Xbox by Microsoft, Play Station by Sony, Wii by Nintendo, etc.), cable television (CATV), satellite television (SATV) and Internet television set-top boxes, digital televisions including high definition television (HDTV), three-dimensional (3DTV) televisions and other types of network devices.

The one or more smart network devices 12, 14, 16 include smart phones such as the iPhone by Apple, Inc., Blackberry Storm and other Blackberry models by Research In Motion, Inc. (RIM), Droid by Motorola, Inc. HTC, Inc. other types of smart phones, etc. However, the present invention is not limited to such smart phone devices, and more, fewer or other devices can be used to practice the invention.

A “smart phone” is a mobile phone that offers more advanced computing ability and connectivity than a contemporary basic feature phone. Smart phones and feature phones may be thought of as handheld computers integrated with a mobile telephone, but while most feature phones are able to run applications based on platforms such as Java ME, a smart phone usually allows the user to install and run more advanced applications. Smart phones and/or tablet computers run complete operating system software providing a platform for application developers.

The operating systems include the iPhone OS, Android, Windows, etc. iPhone OS is a proprietary operating system for the Apple iPhone. The Andriod is an open source operating system platform backed by Google, along with major hardware and software developers (such as Intel, HTC, ARM, Motorola and Samsung, etc.), that form the Open Handset Alliance.

The one or more smart network devices 12, 14, 16 include tablet computers such as the iPad, by Apple, Inc., the HP Tablet, by Hewlett Packard, Inc., the Playbook, by RIM, Inc., the Tablet, by Sony, Inc.

The target network devices 12, 14, 16 are in communications with a cloud communications network 18 via one or more wired and/or wireless communications interfaces. The cloud communications network 18, is also called a “cloud computing network” herein and the terms may be used interchangeably.

The plural server network devices 22, 24, 26 send desired electronic market based estimate content 13, calculated market based estimate content 15, etc. stored on the cloud communications network 18.

The cloud communications network 18 includes, but is not limited to, communications over a wire connected to the target network devices, wireless communications, and other types of communications using one or more communications and/or networking protocols.

Plural server network devices 20, 22, 24, 26 (only four of which are illustrated) each with one or more processors and a non-transitory computer readable medium include one or more associated databases 20′, 22′, 24′, 26′. The plural network devices 20, 22, 24, 26 are in communications with the one or more target devices 12, 14, 16 via the cloud communications network 18.

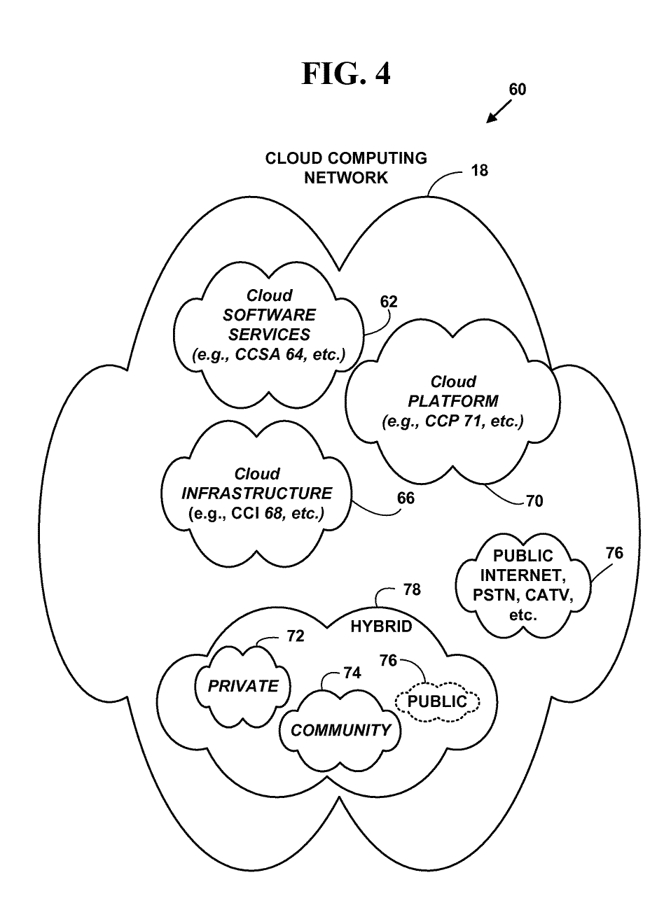

Plural server network devices 20, 22, 24, 26 (only four of which are illustrated) are physically located on one more public networks 76 (See FIG. 4), private networks 72, community networks 74 and/or hybrid networks 78 comprising the cloud network 18.

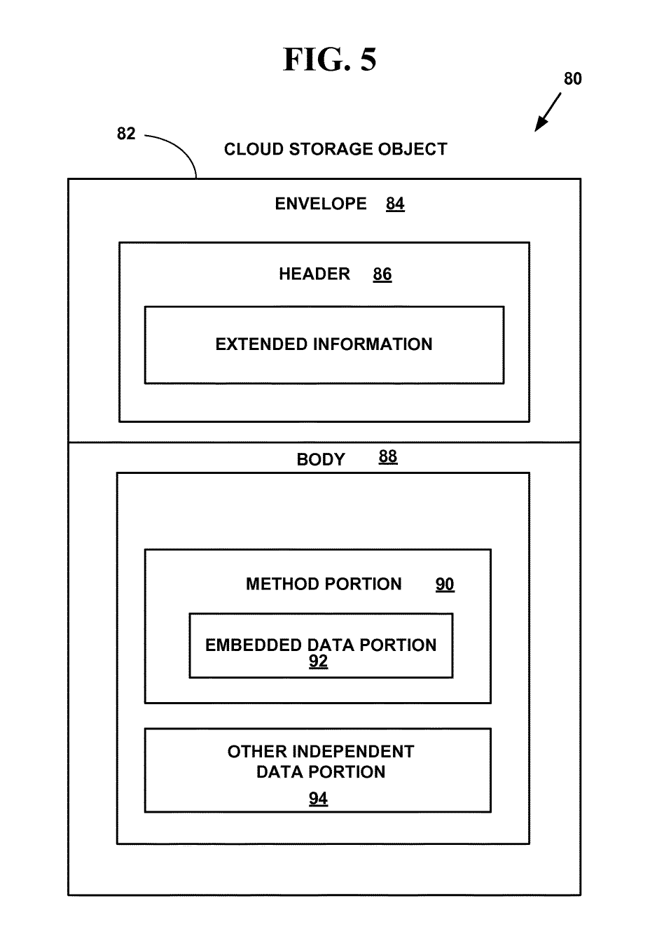

One or more server network devices (e.g., 20, etc.) securely stores a cloud content location map 17 and other plural server network devices (e.g., 22, 24, 26, etc.) store portions 13′, 15′ of desired market based electronic content 13, 15 as cloud storage objects 82 (FIG. 5) as is described herein.

The plural server network devices 20, 22, 24 26, include, but are not limited to, World Wide Web servers, Internet servers, search engine servers, vertical search engine servers, social networking site servers, file servers, other types of electronic information servers, and other types of server network devices (e.g., edge servers, firewalls, routers, gateways, etc.).

The plural server network devices 20, 22, 24, 26 also include, but are not limited to, network servers used for cloud computing providers, etc.

The cloud communications network 18 includes, but is not limited to, a wired and/or wireless communications network comprising one or more portions of: the Internet, an intranet, a Local Area Network (LAN), a wireless LAN (WiLAN), a Wide Area Network (WAN), a Metropolitan Area Network (MAN), a Public Switched Telephone Network (PSTN), a Wireless Personal Area Network (WPAN) and other types of wired and/or wireless communications networks 18.

The cloud communications network 18 includes one or more gateways, routers, bridges and/or switches. A gateway connects computer networks using different network protocols and/or operating at different transmission capacities. A router receives transmitted messages and forwards them to their correct destinations over the most efficient available route. A bridge is a device that connects networks using the same communications protocols so that information can be passed from one network device to another. A switch is a device that filters and forwards packets between network segments based on some pre-determined sequence (e.g., timing, sequence number, etc.).

An operating environment for the network devices of the exemplary market estimate information display system 10 include a processing system with one or more high speed Central Processing Unit(s) (CPU), processors, one or more memories and/or other types of non-transitory computer readable mediums. In accordance with the practices of persons skilled in the art of computer programming, the present invention is described below with reference to acts and symbolic representations of operations or instructions that are performed by the processing system, unless indicated otherwise. Such acts and operations or instructions are referred to as being “computer-executed,” “CPU-executed,” or “processor-executed.”

It will be appreciated that acts and symbolically represented operations or instructions include the manipulation of electrical information by the CPU or processor. An electrical system represents data bits which cause a resulting transformation or reduction of the electrical information or biological information, and the maintenance of data bits at memory locations in a memory system to thereby reconfigure or otherwise alter the CPU's or processor's operation, as well as other processing of information. The memory locations where data bits are maintained are physical locations that have particular electrical, magnetic, optical, or organic properties corresponding to the data bits.

The data bits may also be maintained on a non-transitory computer readable medium including magnetic disks, optical disks, organic memory, and any other volatile (e.g., Random Access Memory (RAM)) or non-volatile (e.g., Read-Only Memory (ROM), flash memory, etc.) mass storage system readable by the CPU. The non-transitory computer readable medium includes cooperating or interconnected computer readable medium, which exist exclusively on the processing system or can be distributed among multiple interconnected processing systems that may be local or remote to the processing system.

### Exemplary Electronic Content Display System

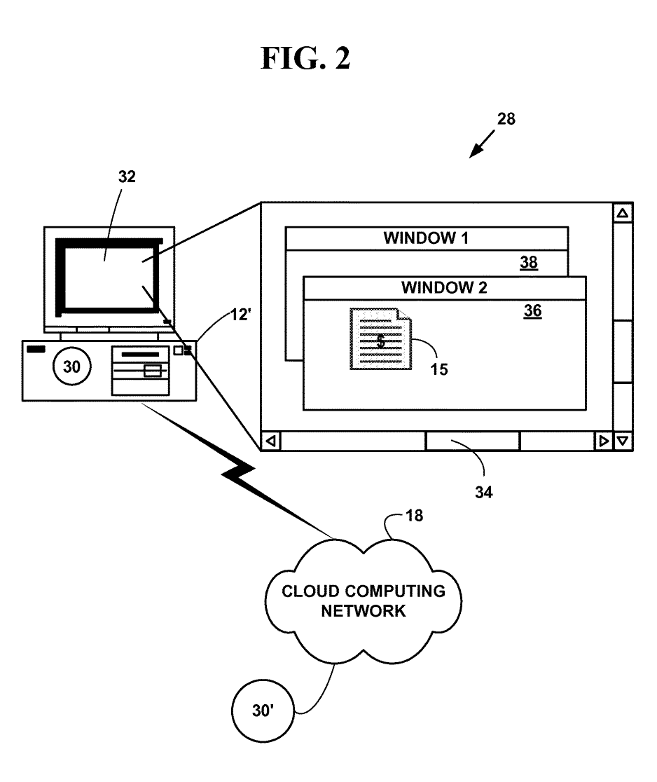

FIG. 2 is a block diagram illustrating an exemplary market estimate information display system 28. The exemplary market estimate information display system includes, but is not limited to a target network device (e.g., 12, etc.) with a cloud application 30 and a display component 32. The cloud application 30 presents a graphical user interface (GUI) 34 on the display 32 component. The GUI 32 presents a multi-window 36, 38, etc. (only two of which are illustrated) interface to a user.

In one embodiment of the invention, the cloud application 30 is a software application. However, the present invention is not limited to this embodiment and the cloud application 30 can be hardware, firmware, hardware and/or any combination thereof. However, the present invention is not limited these embodiments and other embodiments can be used to practice the invention

In another embodiment, a portion of the cloud application 30 is executing on the target network devices 12, 14, 16 and another portion of the application 30′ is executing on the server network devices 20, 22, 24, 26 However, the present invention is not limited these embodiments and other embodiments can be used to practice the invention.

### Exemplary Networking Protocol Stack

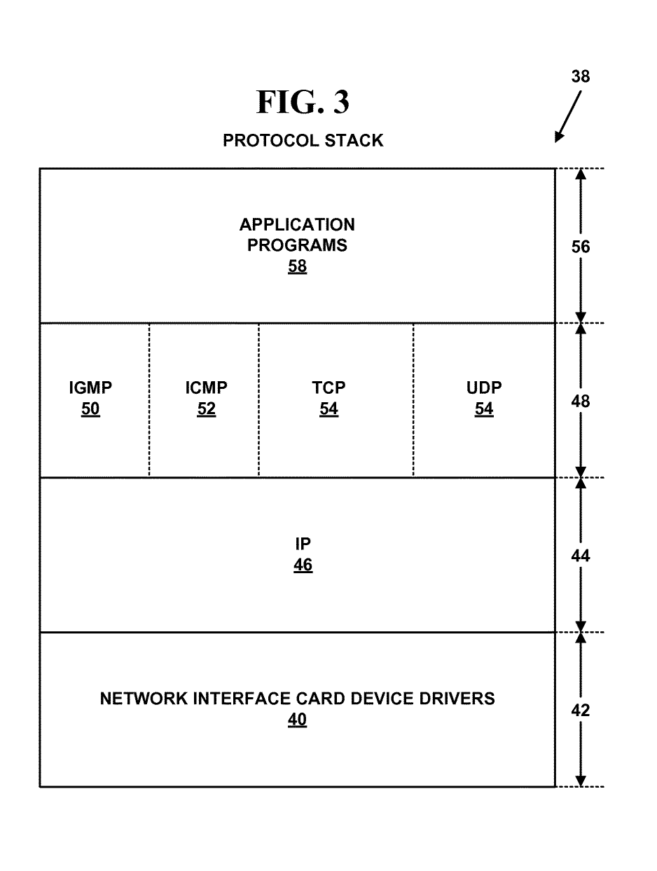

FIG. 3 a block diagram illustrating a layered protocol stack 38 for network devices in the market estimate information display system 10. The layered protocol stack 38 is described with respect to Internet Protocol (IP) suites comprising in general from lowest-to-highest, a link 42, network 44, transport 48 and application 56 layer. However, more or fewer layers could also be used, and different layer designations could also be used for the layers in the protocol stack 38 (e.g., layering based on the Open Systems Interconnection (OSI) model including from lowest-to-highest, a physical, data-link, network, transport, session, presentation and application layer.).

The network devices 12, 14, 16, 20, 22, 24, 26 are connected to the communication network 18 with Network Interface Card (NIC) cards including device drivers 40 in a link layer 42 for the actual hardware connecting the network devices 12, 14, 16, 20, 22, 24, 26 to the cloud communications network 18. For example, the NIC device drivers 40 may include a serial port device driver, a digital subscriber line (DSL) device driver, an Ethernet device driver, a wireless device driver, a wired device driver, etc. The device drivers interface with the actual hardware being used to connect the network devices to the cloud communications network 18. The NIC cards have a medium access control (MAC) address that is unique to each NIC and unique across the whole cloud network 18. The Medium Access Control (MAC) protocol is used to provide a data link layer of an Ethernet USN system and for other network systems.

Above the link layer 42 is a network layer 44 (also called the Internet Layer for Internet Protocol (IP) suites). The network layer 44 includes, but is not limited to, an IP layer 46.

IP 46 is an addressing protocol designed to route traffic within a network or between networks. However, more fewer or other protocols can also be used in the network layer 44, and the present invention is not limited to IP 46. For more information on IP 54 see IETF RFC-791, incorporated herein by reference.

Above network layer 44 is a transport layer 48. The transport layer 48 includes, but is not limited to, an optional Internet Group Management Protocol (IGMP) layer 50, a Internet Control Message Protocol (ICMP) layer 52, a Transmission Control Protocol (TCP) layer 52 and a User Datagram Protocol (UDP) layer 54. However, more, fewer or other protocols could also be used in the transport layer 48.

Optional IGMP layer 50, hereinafter IGMP 50, is responsible for multicasting. For more information on IGMP 50 see RFC-1112, incorporated herein by reference. ICMP layer 52, hereinafter ICMP 52 is used for IP 46 control. The main functions of ICMP 52 include error reporting, reachability testing (e.g., pinging, etc.), route-change notification, performance, subnet addressing and other maintenance. For more information on ICMP 52 see RFC-792, incorporated herein by reference. Both IGMP 50 and ICMP 52 are not required in the protocol stack 38. ICMP 52 can be used alone without optional IGMP layer 50.

TCP layer 54, hereinafter TCP 54, provides a connection-oriented, end-to-end reliable protocol designed to fit into a layered hierarchy of protocols which support multi-network applications. TCP 54 provides for reliable inter-process communication between pairs of processes in network devices attached to distinct but interconnected networks. For more information on TCP 54 see RFC-793, incorporated herein by reference.

UDP layer 56, hereinafter UDP 56, provides a connectionless mode of communications with datagrams in an interconnected set of computer networks. UDP 56 provides a transaction oriented datagram protocol, where delivery and duplicate packet protection are not guaranteed. For more information on UDP 56 see RFC-768, incorporated herein by reference. Both TCP 54 and UDP 56 are not required in protocol stack 38. Either TCP 54 or UDP 56 can be used without the other.

Above transport layer 48 is an application layer 56 where application programs 58 (e.g., 30, 30′, etc.) to carry out desired functionality for a network device reside. For example, the application programs 54 for the client network devices 12, 14, 16 may include a web-browsers or other application programs, cloud application program 30, while application programs for the server network devices 20, 22, 24, 26 may include other application programs (e.g., 30′, etc.).

However, the protocol stack 38 is not limited to the protocol layers illustrated and more, fewer or other layers and protocols can also be used in protocol stack 38. In addition, other protocols from the Internet Protocol suites (e.g., Simple Mail Transfer Protocol, (SMTP), Hyper Text Transfer Protocol (HTTP), File Transfer Protocol (FTP), Dynamic Host Configuration Protocol (DHCP), DNS, etc.) and/or other protocols from other protocol suites may also be used in protocol stack 38.

Preferred embodiments of the present invention include network devices and wired and wireless interfaces that are compliant with all or part of standards proposed by the Institute of Electrical and Electronic Engineers (IEEE), International Telecommunications Union-Telecommunication Standardization Sector (ITU), European Telecommunications Standards Institute (ETSI), Internet Engineering Task Force (IETF), U.S. National Institute of Security Technology (NIST), American National Standard Institute (ANSI), Wireless Application Protocol (WAP) Forum, Bluetooth Forum, or the ADSL Forum. However, network devices based on other standards could also be used.

### Wireless Interfaces

In one embodiment of the present invention, the wireless interfaces on network devices 12, 14, 16, 20, 22, 24, 26 include but are not limited to, 3G and/or 4G IEEE 802.11a, 802.11b, 802.11g, 802.11n, 802.15.4 (ZigBee), “Wireless Fidelity” (Wi-Fi), “Worldwide Interoperability for Microwave Access” (WiMAX), ETSI High Performance Radio Metropolitan Area Network (HIPERMAN) or “RF Home” wireless interfaces. In another embodiment of the present invention, the wireless sensor device may include an integral or separate Bluetooth and/or infra data association (IrDA) module for wireless Bluetooth or wireless infrared communications. However, the present invention is not limited to such an embodiment and other 802.11xx and other types of wireless interfaces can also be used.

802.11b is a short-range wireless network standard. The IEEE 802.11b standard defines wireless interfaces that provide up to 11 Mbps wireless data transmission to and from wireless devices over short ranges. 802.11a is an extension of the 802.11b and can deliver speeds up to 54M bps. 802.11g deliver speeds on par with 802.11a. However, other 802.1lXX interfaces can also be used and the present invention is not limited to the 802.11 protocols defined. The IEEE 802.11a, 802.11b and 802.11g standards are incorporated herein by reference.

Wi-Fi is a type of 802.11xx interface, whether 802.11b, 802.11a, dual-band, etc. Wi-Fi devices include an RF interfaces such as 2.4 GHz for 802.11b or 802.11g and 5 GHz for 802.11a.

802.15.4 (Zigbee) is low data rate network standard used for mesh network devices such as sensors, interactive toys, smart badges, remote controls, and home automation. The 802.15.4 standard provides data rates of 250 kbps, 40 kbps, and 20 kbps., two addressing modes; 16-bit short and 64-bit IEEE addressing, support for critical latency devices, such as joysticks, Carrier Sense Multiple Access/Collision Avoidance, (CSMA-CA) channel access, automatic network establishment by a coordinator, fully handshaked protocol for transfer reliability, power management to ensure low power consumption for multi-month to multi-year battery usage and up to 16 channels in the 2.4 GHz Industrial, Scientific and Medical (ISM) band (Worldwide), 10 channels in the 915 MHz (US) and one channel in the 868 MHz band (Europe). The IEEE 802.15.4-2003 standard is incorporated herein by reference.

WiMAX is an industry trade organization formed by leading communications component and equipment companies to promote and certify compatibility and interoperability of broadband wireless access equipment that conforms to the IEEE 802.16XX and ETSI HIPERMAN. HIPERMAN is the European standard for metropolitan area networks (MAN).

The IEEE The 802.16a and 802.16g standards are wireless MAN technology standard that provides a wireless alternative to cable, DSL and T1/E1 for last mile broadband access. It is also used as complimentary technology to connect IEEE 802.11:XX hot spots to the Internet.

The IEEE 802.16a standard for 2-11 GHz is a wireless MAN technology that provides broadband wireless connectivity to fixed, portable and nomadic devices. It provides up to 50-kilometers of service area range, allows users to get broadband connectivity without needing direct line of sight with the base station, and provides total data rates of up to 280 Mbps per base station, which is enough bandwidth to simultaneously support hundreds of businesses with T1/E1-type connectivity and thousands of homes with DSL-type connectivity with a single base station. The IEEE 802.16g provides up to 100 Mbps.

The IEEE 802.16e standard is an extension to the approved IEEE 802.16/16a/16g standard. The purpose of 802.16e is to add limited mobility to the current standard which is designed for fixed operation.

The ESTI HIPERMAN standard is an interoperable broadband fixed wireless access standard for systems operating at radio frequencies between 2 GHz and 11 GHz.

The IEEE 802.16a, 802.16e and 802.16g standards are incorporated herein by reference. WiMAX can be used to provide a WLP.

The ETSI HIPERMAN standards TR 101 031, TR 101 475, TR 101 493-1 through TR 101 493-3, TR 101 761-1 through TR 101 761-4, TR 101 762, TR 101 763-1 through TR 101 763-3 and TR 101 957 are incorporated herein by reference. ETSI HIPERMAN can be used to provide a WLP.

In one embodiment, the plural server network devices 20, 22, 24, 26 include a connection to plural network interface cards (NICs) in a backplane connected to a communications bus. The NIC cards provide gigabit/second (1×10⁹ bits/second) communications speed of electronic information. This allows “scaling out” for fast electronic content retrieval. The NICs are connected to the plural server network devices 20, 22, 24, 26 and the cloud communications network 18. However, the present invention is not limited to the NICs described and other types of NICs in other configurations and connections with and/or without a buses can also be used to practice the invention.

In one embodiment, network devices 12, 14, 16, 20, 22, 24, 26 and wired and wireless interfaces including the NICs include “4G” components. “4G” refers to the fourth generation of wireless communications standards and speeds of 100 megabits/second to gigabits/second or more. 4G includes peak speed requirements for 4G service at least 100 Mbit/s for high mobility communication (e.g., trains, vehicles, etc.) and 1 Gbit/s for low mobility communication (e.g., pedestrians and stationary users, etc.).

4G technologies are a successor to 3G and 2G standards. The nomenclature of the generations generally refers to a change in the fundamental nature of the service. The first was the move from analogue (IG) to digital (2G) transmission. This was followed by multi-media support, spread spectrum transmission and at least 200 kbits/second (3G). The 4G NICs include IP packet-switched NICs, wired and wireless ultra-broadband (i.e., gigabit speed) access NICs, Worldwide Interoperability for Microwave Access (WiMAX) NICs WiMAX Long Term Evolution (LTE) and/or multi-carrier transmission NICs. However, the present invention is not limited to this embodiment and IG, 2G and 3G and/or any combination thereof, with or with 4G NICs can be used to practice the invention.

In one embodiment of the invention, the WiMAX interfaces includes WiMAX 4G Long Term Evolution (LTE) interfaces. The ITU announced in December 2010 that WiMAX and LTE are 4G technologies. One of the benefits of 4G LTE is the ability to take advantage of advanced topology networks including those on cloud communications networks 18 such as optimized heterogeneous networks with a mix of macrocells with low power nodes such as picocells, femtocells and new relay nodes. LTE further improves the capacity and coverage, and helps ensures user fairness. 4G LTE also introduces multicarrier technologies for ultra-wide bandwidth use, up to 100 MHz of spectrum supporting very high data rates.

In one embodiment, of the invention, the wireless interfaces also include wireless personal area network (WPAN) interfaces. As is known in the art, a WPAN is a personal area network for interconnecting devices centered around an individual person's devices in which the connections are wireless. A WPAN interconnects all the ordinary computing and communicating devices that a person has on their desk (e.g. computer, etc.) or carry with them (e.g., PDA, mobile phone, smart phone, table computer two-way pager, etc.)

A key concept in WPAN technology is known as “plugging in.” In the ideal scenario, when any two WPAN-equipped devices come into close proximity (within several meters and/or feet of each other) or within a few miles and/or kilometers of a central server (not illustrated), they can communicate via wireless communications as if connected by a cable. WPAN devices can also lock out other devices selectively, preventing needless interference or unauthorized access to secure information. Zigbee is one wireless protocol used on WPAN networks such as cloud communications network 18.

However, the present invention is not limited to such wireless interfaces and wireless networks and more, fewer and/or other wireless interfaces can be used to practice the invention.

### Wired Interfaces

In one embodiment of the present invention, the wired interfaces include wired interfaces and corresponding networking protocols for wired connections to the Public Switched Telephone Network (PSTN) and/or a cable television network (CATV) and/or satellite television networks (SATV) and/or three-dimensional television (3DTV), including HDTV that connect the network devices 12, 14, 16, 20, 22, 24, 26 via one or more twisted pairs of copper wires, digital subscriber lines (e.g. DSL, ADSL, VDSL, etc.) coaxial cable, fiber optic cable, other connection media or other connection interfaces. The PSTN is any public switched telephone network provided by AT&T, GTE, Sprint, MCI, SBC, Verizon and others. The CATV is any cable television network provided by the Comcast, Time Warner, etc. However, the present invention is not limited to such wired interfaces and more, fewer and/or other wired interfaces can be used to practice the invention.

### Television Services

In one embodiment, the cloud applications 30, 30′ provide cloud electronic market estimate computing services from television services over the cloud communications network 18. The television services include digital television services, including, but not limited to, cable television, satellite television, high-definition television, three-dimensional, televisions and other types of network devices.

However, the present invention is not limited to such television services and more, fewer and/or other television services can be used to practice the invention.

### Internet Television Services

In one embodiment, the cloud applications 30, 30′ provide cloud electronic market estimate computing services from Internet television services over the cloud communications network 18. The television services include Internet television, Web-TV, and/or Internet Protocol Television (IPtv) and/or other broadcast television services.

“Internet television” allows users to choose a program or the television show they want to watch from an archive of programs or from a channel directory. The two forms of viewing Internet television are streaming content directly to a media player or simply downloading a program to a viewer's set-top box, game console, computer, or other mesh network device.

“Web-TV” delivers digital content via non-mesh broadband and mobile networks. The digital content is streamed to a viewer's set-top box, game console, computer, or other mesh network device.

“Internet Protocol television (IPtv)” is a system through which Internet television services are delivered using the architecture and networking methods of the Internet Protocol Suite over a packet-switched network infrastructure, e.g., the Internet and broadband Internet access networks, instead of being delivered through traditional radio frequency broadcast, satellite signal, and cable television formats.

However, the present invention is not limited to such Internet Television services and more, fewer and/or other Internet Television services can be used to practice the invention.

### General Search Engine Services

In one embodiment, the cloud applications 30, 30′ provide cloud electronic market estimate computing services from general search engine services. A search engine is designed to search for information on a cloud communications network 18 such as the Internet including World Wide Web servers, HTTP, FTP servers etc. The search results are generally presented in a list of electronic results. The information may consist of web pages, images, electronic information, multimedia information, and other types of files. Some search engines also mine data available in databases or open directories. Unlike web directories, which are maintained by human editors, search engines typically operate algorithmically and/or are a mixture of algorithmic and human input.

In one embodiment, the cloud applications 30, 30′ provide cloud electronic market estimate computing services from general search engine services. In another embodiment, the cloud applications 30, 30′ provide general search engine services by interacting with one or more other public search engines (e.g., GOOGLE, BING, YAHOO, etc.) and/or private search engine services.

In another embodiment, the cloud applications 30, 30′ provide electronic market estimate computing services from specialized search engine services, such as vertical search engine services by interacting with one or more other public vertical search engines (e.g., GALAXY.COM, etc.) and/or private search engine services

However, the present invention is not limited to such general and/or vertical search engine services and more, fewer and/or other general search engine services can be used to practice the invention.

### Social Networking Services

In one embodiment, the cloud applications 30, 30′ provide cloud electronic market estimate computing services from one more social networking services including to/from one or more social networking web-sites (e.g., FACEBOOK, YOUTUBE, TWITTER, MY-SPACE, MATCH.COM, E-HARMONY, GROUP ON, SOCIAL LIVING, etc.). The social networking web-sites also include, but are not limited to, social couponing sites, dating web-sites, biogs, RSS feeds, and other types of information web-sites in which messages can be left or posted for a variety of social activities.

However, the present invention is not limited to the social networking services described and other public and private social networking services can also be used to practice the invention.

### Security and Encryption

Network devices 12, 14, 16, 20, 22, 24, 26 with wired and/or wireless interfaces of the present invention include one or more of the security and encryptions techniques discussed herein for secure communications on the cloud communications network 18.

Application programs 58 (FIG. 2) include security and/or encryption application programs integral to and/or separate from the cloud applications 30, 30′ Security and/or encryption programs may also exist in hardware components on the network devices (12, 14, 16, 20, 22, 24, 26) described herein and/or exist in a combination of hardware, software and/or firmware.

Wireless Encryption Protocol (WEP) (also called “Wired Equivalent Privacy) is a security protocol for WiLANs defined in the IEEE 802.11b standard. WEP is cryptographic privacy algorithm, based on the Rivest Cipher 4 (RC4) encryption engine, used to provide confidentiality for 802.11b wireless data.

RC4 is cipher designed by RSA Data Security, Inc. of Bedford, Mass., which can accept encryption keys of arbitrary length, and is essentially a pseudo random number generator with an output of the generator being XORed with a data stream to produce encrypted data.

One problem with WEP is that it is used at the two lowest layers of the OSI model, the physical layer and the data link layer, therefore, it does not offer end-to-end security. One another problem with WEP is that its encryption keys are static rather than dynamic. To update WEP encryption keys, an individual has to manually update a WEP key. WEP also typically uses 40-bit static keys for encryption and thus provides “weak encryption,” making a WEP device a target of hackers.

The IEEE 802.11 Working Group is working on a security upgrade for the 802.11 standard called “802.11i.” This supplemental draft standard is intended to improve WiLAN security. It describes the encrypted transmission of data between systems 802.11X WiLANs. It also defines new encryption key protocols including the Temporal Key Integrity Protocol (TKIP). The IEEE 802.11i draft standard, version 4, completed Jun. 6, 2003, is incorporated herein by reference.

The 802.11i is based on 802.1x port-based authentication for user and device authentication. The 802.11i standard includes two main developments: Wi-Fi Protected Access (WPA) and Robust Security Network (RSN).

WPA uses the same RC4 underlying encryption algorithm as WEP. However, WPA uses TKIP to improve security of keys used with WEP. WPA keys are derived and rotated more often than WEP keys and thus provide additional security. WPA also adds a message-integrity-check function to prevent packet forgeries.

RSN uses dynamic negotiation of authentication and selectable encryption algorithms between wireless access points and wireless devices. The authentication schemes proposed in the draft standard include Extensible Authentication Protocol (EAP). One proposed encryption algorithm is an Advanced Encryption Standard (AES) encryption algorithm.

Dynamic negotiation of authentication and encryption algorithms lets RSN evolve with the state of the art in security, adding algorithms to address new threats and continuing to provide the security necessary to protect information that WiLANs carry.

The NIST developed a new encryption standard, the Advanced Encryption Standard (AES) to keep government information secure. AES is intended to be a stronger, more efficient successor to Triple Data Encryption Standard (3DES).

DES is a popular symmetric-key encryption method developed in 1975 and standardized by ANSI in 1981 as ANSI X.3.92, the contents of which are incorporated herein by reference. As is known in the art, 3DES is the encrypt-decrypt-encrypt (EDE) mode of the DES cipher algorithm. 3DES is defined in the ANSI standard, ANSI X9.52-1998, the contents of which are incorporated herein by reference. DES modes of operation are used in conjunction with the NIST Federal Information Processing Standard (PIPS) for data encryption (PIPS 46-3, October 1999), the contents of which are incorporated herein by reference.

The NIST approved a PIPS for the AES, FIPS-197. This standard specified “Rijndael” encryption as a PIPS-approved symmetric encryption algorithm that may be used by U.S. Government organizations (and others) to protect sensitive information. The NIST FIPS-197 standard (AES PIPS PUB 197, November 2001) is incorporated herein by reference.

The NIST approved a PIPS for U.S. Federal Government requirements for information technology products for sensitive but unclassified (SBU) communications. The NIST PIPS Security Requirements for Cryptographic Modules (PIPS PUB 140-2, May 2001) is incorporated herein by reference.

RSA is a public key encryption system which can be used both for encrypting messages and making digital signatures. The letters RSA stand for the names of the inventors: Rivest, Shamir and Adleman. For more information on RSA, see U.S. Pat. No. 4,405,829, now expired, incorporated herein by reference.

“Hashing” is the transformation of a string of characters into a usually shorter fixed-length value or key that represents the original string. Hashing is used to index and retrieve items in a database because it is faster to find the item using the shorter hashed key than to find it using the original value. It is also used in many encryption algorithms.

Secure Hash Algorithm (SHA), is used for computing a secure condensed representation of a data message or a data file. When a message of any length <2⁶⁴ bits is input, the SHA-I produces a 160-bit output called a “message digest.” The message digest can then be input to other security techniques such as encryption, a Digital Signature Algorithm (DSA) and others which generates or verifies a security mechanism for the message. SHA-512 outputs a 512-bit message digest. The Secure Hash Standard, PIPS PUB 180-1, Apr. 17, 1995, is incorporated herein by reference.

Message Digest-5 (MD-5) takes as input a message of arbitrary length and produces as output a 128-bit “message digest” of the input. The MD5 algorithm is intended for digital signature applications, where a large file must be “compressed” in a secure manner before being encrypted with a private (secret) key under a public-key cryptosystem such as RSA. The IETF RFC-1321, entitled “The MD5 Message-Digest Algorithm” is incorporated here by reference.

Providing a way to check the integrity of information transmitted over or stored in an unreliable medium such as a wireless network is a prime necessity in the world of open computing and communications. Mechanisms that provide such integrity check based on a secret key are called “message authentication codes” (MAC). Typically, message authentication codes are used between two parties that share a secret key in order to validate information transmitted between these parties.

Keyed Hashing for Message Authentication Codes (HMAC), is a mechanism for message authentication using cryptographic hash functions. HMAC is used with any iterative cryptographic hash function, e.g., MD5, SHA-I, SHA-512, etc. in combination with a secret shared key. The cryptographic strength of HMAC depends on the properties of the underlying hash function. The IETF RFC-2101, entitled “HMAC: Keyed-Hashing for Message Authentication” is incorporated here by reference.

An Electronic Code Book (ECB) is a mode of operation for a “block cipher,” with the characteristic that each possible block of plaintext has a defined corresponding cipher text value and vice versa. In other words, the same plaintext value will always result in the same cipher text value. Electronic Code Book is used when a volume of plaintext is separated into several blocks of data, each of which is then encrypted independently of other blocks. The Electronic Code Book has the ability to support a separate encryption key for each block type.

Diffie and Hellman (DH) describe several different group methods for two parties to agree upon a shared secret in such a way that the secret will be unavailable to eavesdroppers. This secret is then converted into various types of cryptographic keys. A large number of the variants of the DH method exist including ANSI X9.42. The IETF RFC-2631, entitled “Diffie-Hellman Key Agreement Method” is incorporated here by reference.

The HyperText Transport Protocol (HTTP) Secure (HTTPs), is a standard for encrypted communications on the World Wide Web. HTTPs is actually just HTTP over a Secure Sockets Layer (SSL). For more information on HTTP, see IETF RFC-2616 incorporated herein by reference.

The SSL protocol is a protocol layer which may be placed between a reliable connection-oriented network layer protocol (e.g. TCP/IP) and the application protocol layer (e.g. HTTP). SSL provides for secure communication between a source and destination by allowing mutual authentication, the use of digital signatures for integrity, and encryption for privacy.

The SSL protocol is designed to support a range of choices for specific security methods used for cryptography, message digests, and digital signatures. The security method are negotiated between the source and destination at the start of establishing a protocol session. The SSL 2.0 protocol specification, by Kipp E. B. Hickman, 1995 is incorporated herein by reference. More information on SSL is available at the domain name See “netscape.com/eng/security/SSL_2.html.”

Transport Layer Security (TLS) provides communications privacy over the Internet. The protocol allows client/server applications to communicate over a transport layer (e.g., TCP) in a way that is designed to prevent eavesdropping, tampering, or message forgery. For more information on TLS see IETF RFC-2246, incorporated herein by reference.

In one embodiment, the security functionality includes Cisco Compatible EXtensions (CCX). CCX includes security specifications for makers of 802.11xx wireless LAN chips for ensuring compliance with Cisco's proprietary wireless security LAN protocols. As is known in the art, Cisco Systems, Inc. of San Jose, Calif. is supplier of networking hardware and software, including router and security products.

However, the present invention is not limited to such security and encryption methods described herein and more, fewer and/or other types of security and encryption methods can be used to practice the invention. The security and encryption methods described herein can also be used in various combinations and/or in different layers of the protocol stack 38 with each other.

### Cloud Computing Networks

FIG. 4 is a block diagram 60 illustrating an exemplary cloud computing network 18. The cloud computing network 18 is also referred to as a “cloud communications network” 18. However, the present invention is not limited to this cloud computing model and other cloud computing models can also be used to practice the invention. The exemplary cloud communications network includes both wired and/or wireless components of public and private networks.

In one embodiment, the cloud computing network 18 includes a cloud communications network 18 comprising plural different cloud component networks 72, 74, 76, 78. “Cloud computing” is a model for enabling, on-demand network access to a shared pool of configurable computing resources (e.g., public and private networks, servers, storage, applications, and services) that are shared, rapidly provisioned and released with minimal management effort or service provider interaction.

This exemplary cloud computing model for electronic information retrieval promotes availability for shared resources and comprises: (1) cloud computing essential characteristics; (2) cloud computing service models; and (3) cloud computing deployment models. However, the present invention is not limited to this cloud computing model and other cloud computing models can also be used to practice the invention.

Exemplary cloud computing essential characteristics appear in Table 1. However, the present invention is not limited to these essential characteristics and more, fewer or other characteristics can also be used to practice the invention.

TABLE 1
On-demand electronic market estimate calculation computing services.

Electronic market estimators can unilaterally provision computing
capabilities, such as server time and network storage, as needed automatically
without requiring human interaction with each network server on the cloud
communications network 18.

Broadband network access. Electronic market estimators capabilities are

available over plural broadband communications networks and accessed
through standard mechanisms that promote use by heterogeneous thin or
thick client platforms (e.g., mobile phones, smart phones 14, tablet
computers 12, laptops, PDAs, etc.). The broadband network access
includes high speed network access such as 3G and/or 4G wireless and/or
wired and broadband and/or ultra-broad band (e.g., WiMAX, etc.) network
access.

Resource pooling. Electronic market estimators computing resources are pooled

to serve multiple requesters using a multi-tenant model, with different
physical and virtual resources dynamically assigned and reassigned
according to electronic market estimator calculation demand. There is
location independence in that an requester of electronic content has no
control and/or knowledge over the exact location of the provided by the
electronic market estimator calculation resources but may be able to
specify location at a higher level of abstraction (e.g., country, state, or data
center). Examples of pooled resources include storage, processing,
memory, network bandwidth, virtual server network device and virtual target
network devices.

Rapid elasticity. Capabilities can be rapidly and elastically provisioned, in some

cases automatically, to quickly scale out and rapidly released to quickly
scale for electronic market estimation calculation. To the electronic
market estimator calculation services, the electronic market estimator
calculation capabilities available for provisioning appear to be unlimited
and can be used in any quantity at any time.

Measured Services. Cloud computing systems automatically control and optimize

resource use by leveraging a metering capability at some level of
abstraction appropriate to the type of electronic market estimators service
(e.g., calculating, processing, bandwidth, custom electronic market
estimators applications, etc.). Electronic market estimation calculation
usage is monitored, controlled, and reported providing transparency for
both the electronic market estimator calculations and the electronic market
estimation information providers of the utilized electronic market estimators
service.

Exemplary cloud computing service models illustrated in FIG. 4 appear in Table 2. However, the present invention is not limited to these service models and more, fewer or other service models can also be used to practice the invention.

TABLE 2
Cloud Computing Software Applications 62 for an Electronic Market

Estimation Calculation Service (CCSA 64). The capability to use the
provider's applications 30, 30′ running on a cloud infrastructure 66. The
cloud computing applications 62, are accessible from the server network
device 20 from various client devices 12, 14, 16 through a thin client
interface such as a web browser, etc. The user does not manage or control
the underlying cloud infrastructure 66 including network, servers,
operating systems, storage, or even individual application 30, 30′
capabilities, with the possible exception of limited user-specific application
configuration settings.

Cloud Computing Infrastructure 66 for the an Electronic Market Estimation

Calculation Service (CCI 68). The capability provided to the user is to
provision processing, storage and retrieval, networks 18, 72, 74, 76, 78
and other fundamental computing resources where the consumer is able to
deploy and run arbitrary software, which can include operating systems
and applications 30, 30′. The user does not manage or control the
underlying cloud infrastructure 66 but has control over operating systems,
storage, deployed applications, and possibly limited control of select networking
components (e.g., host firewalls, etc.).

Cloud Computing Platform 70 for the an Electronic Market Estimation

Calculation Service (CCP 71). The capability provided to the user to
deploy onto the cloud infrastructure 66 created or acquired applications
created using programming languages and tools supported servers 20, 22,
24, 26, etc.. The user not manage or control the underlying cloud
infrastructure 66 including network, servers, operating systems, or storage,
but has control over the deployed applications 30, 30′ and possibly application
hosting environment configurations.

Exemplary cloud computing deployment models appear in Table 3. However, the present invention is not limited to these deployment models and more, fewer or other deployment models can also be used to practice the invention.

TABLE 3
Private cloud network 72. The cloud network infrastructure is operated solely for

electronic market estimation calculations It may be managed by the
electronic content retrieval or a third party and may exist on premise or off
premise.

Community cloud network 74. The cloud network infrastructure is shared by

several different organizations and supports a specific electronic market
estimation content community that has shared concerns (e.g., mission,
security requirements, policy, compliance considerations, etc.). It may be
managed by the different organizations or a third party and may exist on premise
or off premise.

Public cloud network 76. The cloud network infrastructure such as the Internet,

PSTN, SATV, CATV, Internet TV, etc. is made available to the general public
or a large industry group and is owned by one or more organizations selling
cloud services.

Hybrid cloud network 78. The cloud network infrastructure 66 is a composition

of two and/or more cloud networks 18 (e.g., private 72, community 74,
and/or public 76, etc.) and/or other types of public and/or private networks (e.g.,
intranets, etc.) that remain unique entities but are bound together by standardized
or proprietary technology that enables data and application portability (e.g.,
cloud bursting for load-balancing between clouds, etc.)

Cloud software 64 for electronic market estimation takes full advantage of the cloud paradigm by being service oriented with a focus on statelessness, low coupling, modularity, and semantic interoperability for electronic content retrieval. However, cloud software services 64 can include various states.

Cloud storage of desired electronic content on a cloud computing network includes agility, scalability, elasticity and multi-tenancy. Although a storage foundation may be comprised of block storage or file storage such as that exists on conventional networks, cloud storage is typically exposed to requesters of desired electronic content as cloud objects.

In one exemplary embodiment, the cloud application 30′, offers cloud services for electronic market estimation calculations. The application 30, 30′ offers the cloud computing infrastructure 66, 68_{—!S} §.ervice 62 (IaaS), including a cloud software infrastructure service 62, the cloud Platform 70, 71 as a Service 62 (PaaS) including a cloud software platform service 62 and/or offers Specific cloud software services as a Service 62 (SaaS) including a specific cloud software service 62 for electronic market estimation. The IaaS, PaaS and SaaS include one or more of cloud services 62 comprising networking, storage, server network device, virtualization, operating system, middleware, run-time, data and/or application services, or plural combinations thereof, on the cloud communications network 18.

FIG. 5 is a block diagram 80 illustrating an exemplary cloud storage object 82.

The cloud storage object 82 includes an envelope portion 84, with a header portion 86, and a body portion 88. However, the present invention is not limited to such a cloud storage object 82 and other cloud storage objects and other cloud storage objects with more, fewer or other portions can also be used to practice the invention.

The envelope portion 84 uses unique namespace Uniform Resource Identifiers (URis) and/or Uniform Resource Names (URNs), and/or Uniform Resource Locators (URLs) unique across the cloud communications network 18 to uniquely specify, location and version information and encoding rules used by the cloud storage object 82 across the whole cloud communications network 18. For more information, see IETF RFC-3305, Uniform Resource Identifiers (URis), URLs, and Uniform Resource Names (URNs), the contents of which are incorporated by reference.

The envelope portion 84 of the cloud storage object 82 is followed by a header portion 86. The header portion 86 includes extended information about the cloud storage objects such as authorization and/or transaction information, etc.

The body portion 88 includes methods 90 (i.e., a sequence of instructions, etc.) for using embedded application-specific data in data elements 92. The body portion 88 typically includes only one portion of plural portions of application-specific data 92 and independent data 94 so the cloud storage object 82 can provide distributed, redundant fault tolerant, security and privacy features described herein.

Cloud storage objects 82 have proven experimentally to be a highly scalable, available and reliable layer of abstraction that also minimizes the limitations of common file systems. Cloud storage objects 82 also provide low latency and low storage and transmission costs.

Cloud storage objects 82 are comprised of many distributed resources, but function as a single storage object, are highly fault tolerant through redundancy and provide distribution of desired electronic content across public communication networks 76, and one or more private networks 72, community networks 74 and hybrid networks 78 of the cloud communications network 18. Cloud storage objects 82 are also highly durable because of creation of copies of portions of desired electronic content across such networks 72, 74, 76, 78 of the cloud communications network 18. Cloud storage objects 82 includes one or more portions of desired electronic content and can be stored on any of the 72, 74, 76, 78 networks of the cloud communications network 18. Cloud storage objects 82 are transparent to a requester of desired electronic content and are managed by cloud applications 30, 30′.

In one embodiment, cloud storage objects 82 are configurable arbitrary objects with a size up to hundreds of terabytes, each accompanied by with a few kilobytes of metadata. Cloud objects are organized into and identified by a unique identifier unique across the whole cloud communications network 18. However, the present invention is not limited to the cloud storage objects described, and more fewer and other types of cloud storage objects can be used to practice the invention.

Cloud storage objects 82 present a single unified namespace or object-space and manages desired electronic content by user or administrator-defined policies storage and retrieval policies. Cloud storage objects includes Representational state transfer (REST), Simple Object Access Protocol (SOAP), Lightweight Directory Access Protocol (LDAP) and/or Application Programming Interface (API) objects and/or other types of cloud storage objects. However, the present invention is not limited to the cloud storage objects described, and more fewer and other types of cloud storage objects can be used to practice the invention.

REST is a protocol specification that characterizes and constrains macro-interactions storage objects of the four components of a cloud communications network 18, namely origin servers, gateways, proxies and clients, without imposing limitations on the individual participants.

SOAP is a protocol specification for exchanging structured information in the implementation of cloud services with storage objects. SOAP has at least three major characteristics: (1) Extensibility (including security/encryption, routing, etc.); (2) Neutrality (SOAP can be used over any transport protocol such as HTTP, SMTP or even TCP, etc.), and (3) Independence (SOAP allows for almost any programming model to be used, etc.)

LDAP is a software protocol for enabling storage and retrieval of electronic content and other resources such as files and devices on the cloud communications network 18. LDAP is a “lightweight” version of Directory Access Protocol (DAP), which is part of X.500, a standard for directory services in a network. LDAP may be used with X.509 security and other security methods for secure storage and retrieval. X.509 is public key digital certificate standard developed as part of the X.500 directory specification. X.509 is used for secure management and distribution of digitally signed certificates across networks.

An API is a particular set of rules and specifications that software programs can follow to communicate with each other. It serves as an interface between different software programs and facilitates their interaction.

### Hedge Funds

A “hedge fund” is an alternative investment that is designed to protect investment portfolios from market uncertainty, while generating positive returns in both up and down markets. A hedge fund is typically a private investment fund which may invest in a diverse range of assets and may employ a variety of investment strategies to maintain a hedged portfolio intended to protect the fund's investors from downturns in the market while maximizing returns on market upswings.

Hedge funds are distinct from mutual funds, individual retirement and investment accounts, and other types of traditional investment portfolios in a number of ways. As a class, hedge funds undertake a wider range of investment and trading activities than traditional long-only investment funds, and invest in a broader range of assets, including equities, bonds and commodities. By taking a long position on a particular asset a hedge fund manager is asserting that this position is likely to increase in value. When the hedge manager takes a short position in another asset they would be asserting that the asset is likely to decrease in value.

In general, hedge fund indices provide performance benchmarks based on a large and representative sample of hedge funds. For example, hedge fund indices focus on capturing the average return and risk characteristics of hedge funds viewed as an asset class, rather than attempting to outperform the asset class by choosing better performing hedge funds for the hedge fund index.

A hedge fund index is typically published on a pre-determined (e.g., monthly) basis and typically represent the weighted average performance of hedge funds included in the hedge fund index. The performance can be calculated and published for the overall index, as well as for various subsets of the overall index as defined, for example, by an investment strategy, geographical location, assets under management, etc.

The present invention can be used with hedge funds, hedge funds indicies and other types of hedge fund information.

### LIBOR

The London Interbank Offered Rate is the average interest rate estimated by leading banks in London that they would be charged if borrowing from other banks. It is usually abbreviated LIBOR or BBA LIBOR (for British Bankers' Association Libor) LIBOR is the primary benchmark, along with the Euribor, for short term interest rates around the world.

LIBOR rates are calculated for ten different currencies and 15 borrowing periods ranging from overnight to one year and are published daily at 11:30 am (London time). Many financial institutions, mortgage lenders and credit card agencies set their own rates relative to it. Trillions of dollars in derivatives and other financial products are tied to the LIBOR.

LIBOR is defined as: “The rate at which an individual contributor panel bank could borrow funds, were it to do so by asking for and then accepting inter-bank offers in reasonable market size, just prior to 11:00 am, London, England time.

The LIBOR definition further states: (1) a rate at which each bank submits must be formed from that bank's perception of its cost of funds in the interbank market; (2) contributions must represent rates formed in London and not elsewhere; (3) Contributions must be for the currency concerned, not the cost of producing one currency by borrowing in another currency and accessing the required currency via the foreign exchange markets; (4) The rates must be submitted by members of staff at a bank with primary responsibility for management of a bank's cash, rather than a bank's derivative book; (5) The definition of “funds” is: unsecured interbank cash or cash raised through primary issuance of interbank Certificates of Deposit; and (6) The British Bankers' Association publishes a basic guide to the BBA Libor which contains a great deal of detail as to its history and its current calculation.

LIBOR is calculated and published by Thomson Reuters on behalf of the BBA. It is an index that measures the cost of funds to large global banks operating in London financial markets or with London-based counterparties. Each day, the BBA surveys a panel of banks (18 major global banks for the USD Libor), asking the question, “At what rate could you borrow funds, where you to do so by asking for and then accepting inter-bank offers in a reasonable market size just prior to 11 am?” The BBA throws out the highest 4 and lowest 4 responses, and averages the remaining middle ten.

The average is reported at 11:30 a.m. LIBOR is actually a set of indexes. There are separate LIBOR rates reported for 15 different maturities (length of time to repay a debt) for each of 10 currencies. The shortest maturity is overnight, the longest is one year. In the United States, many private contracts reference the three-month dollar LIBOR, which is the index resulting from asking the panel what rate they would pay to borrow dollars for three months.

LIBOR initially fixed rates for three currencies. These were the U.S. dollar, British pound sterling and Japanese yen. In the years following its introduction there were sixteen currencies. After a number of these currencies in 2000 merged into the Euro there remained ten currencies: (1) Australian Dollar; (2) British pound sterling; (3) Canadian dollar; (4) Japanese yen; (5) Swiss franc; (6) New Zealand dollar; (7) Danish krone; (8) Swedish krona; (9) Euro and (10) U.S. dollar. LIBOR durations time periods include: (1) one day; (2) one week; (3) two weeks; and (4) one month to 12 months.

The Singapore Interbank Offered Rate (SIBOR) and is a daily reference rate based on the interest rates at which banks offer to lend unsecured funds to other banks in the Singapore wholesale money market (or interbank market). Hong Kong Inter-bank Offered Rate (HIBOR) is an annualized offer rate banks in Hong Kong, China offer for a specified period ranging from overnight to one year.

Electronic Market Estimation with Market Based Measures

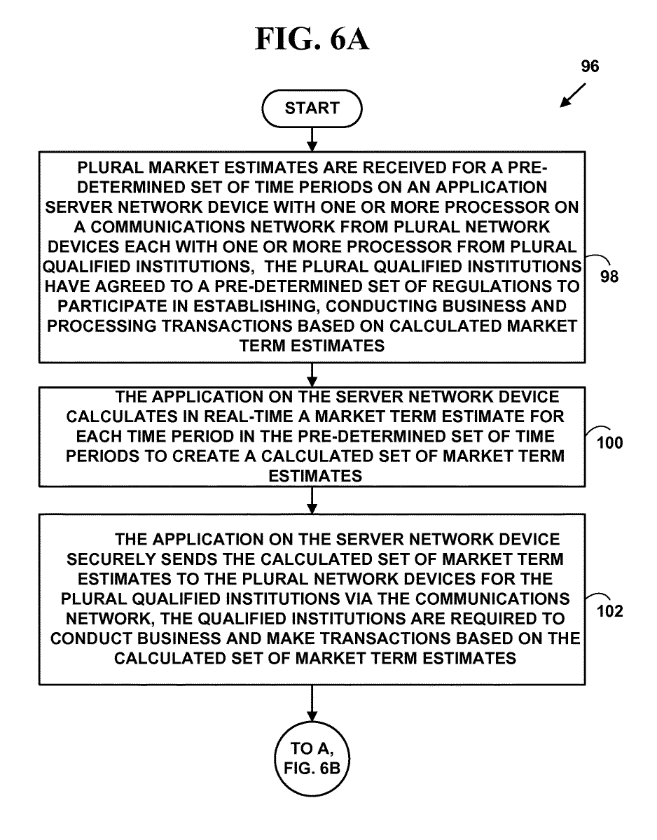

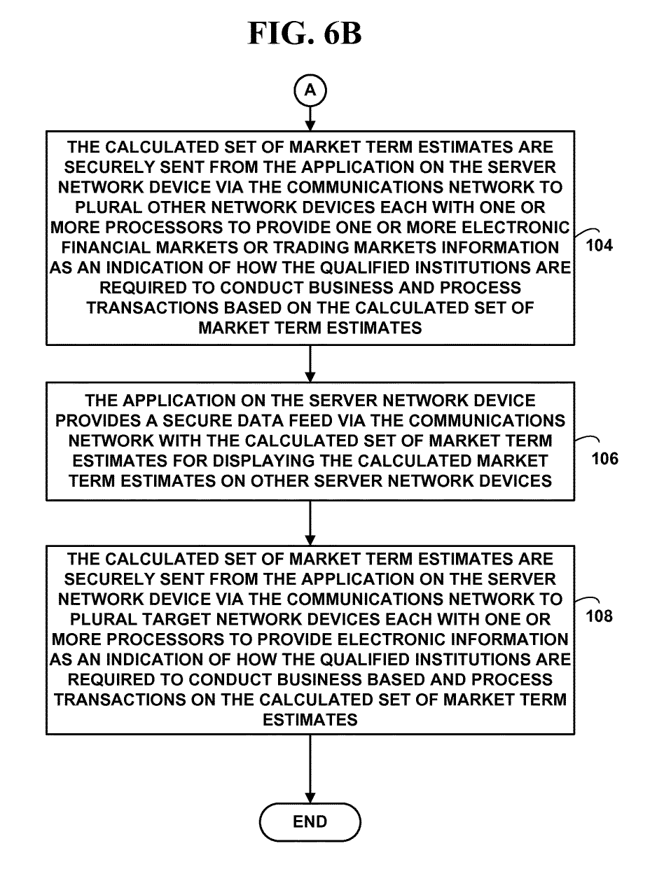

FIGS. 6A and 6B are a flow diagram illustrating a Method 96 for electronic market estimation with market based measures. In FIG. 6A at Step 98, plural market estimates are received for a pre-determined set of time periods on an application server network device with one or more processor on a communications network from plural network devices each with one or more processor from plural qualified institutions. The plural qualified institutions have agreed to a pre-determined set of regulations to participate in establishing, conducting business and processing transactions based on calculated market term estimates. At Step 100, the application on the server network device calculates in real-time a market term estimate for each time period in the pre-determined set of time periods to create a calculated set of market term estimates. At Step 102, the application on the server network device securely sends the calculated set of market term estimates to the plural network devices for the plural qualified institutions via the communications network. The qualified institutions are required to conduct business and make transactions based on the calculated set of market term estimates. In FIG. 6B at Step 104, the calculated set of market term estimates are securely sent from the application on the server network device via the communications network to plural other network devices each with one or more processors to provide one or more electronic markets or trading markets information as an indication of how the qualified institutions are required to conduct business and process transactions based on the calculated set of market term estimates. At Step 106, the application on the server network device provides a secure data feed via the communications network with the calculated set of market term estimates for displaying the calculated market term estimates on other server network devices. At Step 108, the calculated set of market term estimates are securely sent from the application on the server network device via the communications network to plural target network devices each with one or more processors to provide electronic information as an indication of how the qualified institutions are required to conduct business based and process transactions on the calculated set of market term estimates.

Method 96 is illustrated with an exemplary embodiment. However, the present invention is not limited to this embodiment and other embodiments can be used to practice the invention.

In such an exemplary embodiment, in FIG. 6A at Step 98, plural market estimates 13 are received for a pre-determined set of time periods on an application 30′ on a server network device 20 with one or more processor on a communications network 18 from plural network devices 22, 24, 26 each with one or more processor for plural qualified institutions. The plural qualified institutions have agreed to a pre-determined set of regulations to participate in establishing and conducting business based on calculated market term estimates 15.

The qualified institutions include, but are not limited to, financial institutions (e.g., banks, etc.), industrial institutions (e.g., public and private companies in a specific industry (e.g., automobile, housing, manufacturing, food processing, etc.), utility institutions (e.g., electric, natural gas, heating oil, etc.) trading institutions (e.g., stock, bonds, commodities, options, etc.) data providing institutions (e.g., news services Thomson Reuters New Services, Dow Jones News Service, social networking sites, other trading news services, financial news services etc.), environmental institutions and other institutions that provide any type of goods and/or services. The qualified institutions may be public and/or private qualified institutions. However, the present invention is not limited to such an embodiment and more, fewer and other types of qualified institutions can be used to practice the invention.

In another embodiment, non-market estimates can also be received at Step 98. In addition, at Step 98, the market estimates or non-market estimates can be received privately and/or anonymously and used to create the calculated set of market term estimates that are publically displayed and publically used. The calculated set of market term estimates can also be used privately only by the participating qualified institutions.

Non-market estimates include methods to estimate values of goods and services that are not commonly bought and sold in defined markets. Whereas sale prices do give indications of the monetary value for goods and services that are routinely bought and sold, for certain goods and services non-market and/or non-monetary alternatives data is used directly and/or converted and compared in monetary terms.

As an example to illustrate Method 96, consider Banks A to J that represent participating qualified financial institutions who set (i.e., provide rates and size) an overnight interest rate. Such banks may submit data as an interest rate alone or as an interest rate and size as a market estimate.

Table 4 illustrates exemplary market estimates 13 received at Step 98 from the exemplary Banks A to J.

TABLE 4

| | Bank | | |
|---|---|---|---|
| S. No | Name | Overnight Rate Submissions | Overnight Night Size ($) |
| 1 | Bank A | 0.050% | $100,000 |
| 2 | Bank B | 0.067% | $50,000 |
| 3 | Bank C | 0.090% | $150,000 |
| 4 | Bank D | 0.088% | $25,000 |
| 5 | Bank E | 0.068% | $50,000 |
| 6 | Bank F | 0.050% | $250,000 |
| 7 | Bank G | 0.045% | $65,000 |
| 8 | Bank H | 0.072% | $55,000 |
| 9 | Bank I | 0.050% | $75,000 |
| 10 | Bank J | 0.062% | $75,000 |

At Step 100, the application 30′ on the server network device 20 calculates in real-time (i.e., in about a few seconds or less, etc.) a market term estimate for each time period in the pre-determined set of time periods to create a calculated set of market term estimates.

In one embodiment, Step 100 includes arranging the plural market estimates for each period are arranged in ascending order. The top 20% of the received entries and bottom 20% of the received market based estimates 13 are eliminated. A term estimate for each period is then calculated as a simple arithmetic average of a remaining entries per period.

Table 5 illustrates such an exemplary calculation at Step 100 using the received market term estimates 15 illustrated in Table 4. As is shown in Table 5, the received market estimates from Table 4 are arranged in ascending order. The top and bottom 20% are eliminated. The averages of the remaining received market estimates are used to calculate an arithmetic average of the remaining received market estimates 13.

TABLE 5

| | | Overnight | | | |
|---|---|---|---|---|---|
| | | Rates (in | | | |
| | Bank | ascending | Overnight | | |
| | Name | order) | Size ($) | Action | |
| 7 | Bank G | 0.045% | $65,000 | Eliminated | |
| 1 | Bank A | 0.050% | $100,000 | Eliminated | |
| 6 | Bank F | 0.050% | $250,000 | | Rate based on |
| 9 | Bank I | 0.050% | $75,000 | | Simple Average: |
| 10 | Bank J | 0.062% | $75,000 | | 0.0614% |
| 2 | Bank B | 0.067% | $50,000 | {close oversize brace} | Rate based on |
| 5 | Bank E | 0.068% | $50,000 | | Volume Weighted |
| 8 | Bank H | 0.072% | $55,000 | | Average: 0.0569% |
| 4 | Bank D | 0.088% | $25,000 | Eliminated | |
| 3 | Bank C | 0.090% | $150,000 | Eliminated | |

As is illustrated in Table 5, an overnight interest rate is calculated using the simple average of overnight rates. The calculated value is 0.0614%.

As an alternate method, a term estimate for each period may be arrived as a volume weighted average of received entries and its accompanying size. However, the present invention is not limited to such calculations and other calculations can be used to practice the invention. The alternative method with volume weighted average using size and rates is 0.0569% for the same entries in Table 5.

However, the present invention is not limited to such embodiments and other embodiments and a large number of other calculation methods can be used at Step 100 to calculate the set of market term estimates.

In one embodiment, the calculated set of market term estimates 15 includes LIBOR, SIBOR and/or HIBOR estimates. In another embodiment, the created set of market term estimates includes estimates such as interest rates, indices, buy and or sell prices for stocks, bonds, options, commodities, hedge funds and/or any other goods and/or services sold, traded or exchanged via a defined market. The defined market may regulated or unregulated markets. The calculated set of market term estimates 15 can be used on a regulated trading exchange or an unregulated trading exchange. Non-market estimates can also be used to create the set of market term estimates. However, the present invention is not limited to such an embodiment and other embodiments can be used to practice the invention.

At Step 102, the application 30′ on the server network device 20 sends the calculated set of market term estimates 15 to the plural network devices 22, 24, 26 for the plural qualified institutions via the communications network 18. The qualified institutions are required to conduct business and make transactions based on the calculated set of market term estimates 15.

Once the calculated set of market term estimates 15 has been established, the qualified institutions must make actual transactions using the calculated set of market term estimates 15. This is illustrated with an exemplary supply-demand curve in Table 6. The example in Table 6 assumes the use of the simple average method discussed above used at Step 100.

TABLE 6

| Overnight | Offered Amount | Borrowed Amount |
|---|---|---|
| Rate | ($) | ($) |
| 0.081% | $250,000 | |
| 0.076% | $200,000 | |
| 0.071% | $150,000 | |
| 0.066% | $100,000 | |

| | |
|---|---|
| 0.061% | Equilibrium Overnight Rate |

| | |
|---|---|
| 0.056% | $100,000 |
| 0.051% | $150,000 |
| 0.046% | $200,000 |
| 0.041% | $250,000 |

As illustrated in Table 6, members of the group of qualified financial institutions (i.e., Banks A through J) must be willing to offer greater and greater amounts of funds above equilibrium rate.

Similarly, members of the group of qualified institutions must be willing to borrow greater and greater amounts for successive rates below the equilibrium rates. All qualified institutions members have to be involved in fund transactions (i.e., borrow or lend to other members and others) that satisfy the above supply-demand curve in Table 6.

Such transactions are done electronically and are cleared electronically to ensure the qualified institutions comply with the established market term estimates. Once a given level of transactions adds credibility to an established equilibrium rate illustrated in Table 6, it is published widely as is illustrated by Steps 104-108. However, the present invention is not limited to the supply and demand curve or equilibrium rate illustrated in Table 6 and other supply and demand curves, other equilibrium rates and other entities can also be used to practice the invention.

In FIG. 6B Step 104, the calculated set of market term estimates 15 are securely sent from the application 30′ on the server network device 20 to plural other network devices 22, 24, 26 each with one or more processors to provide one or more electronic markets or trading markets information as an indication of how the qualified institutions are required to conduct business and process transactions based on the calculated set of market term estimates 15.

At Step 106, the application 30′ on the server network device 20 provides a secure data feed via the communications network 18 with the calculated set of market term estimates 15 for displaying the calculated market term estimates on other server network devices 22, 24, 26.

At Step 108, the calculated set of market term estimates 15 are securely sent from the application 30′ on the server network device 20 to plural target network devices 12, 14, 16 each with one or more processors to provide electronic information as an indication of how the qualified institutions are required to conduct business based on the calculated set of market term estimates 15.

The calculated set of market term estimates 15 are displayed from on a graphical user interface 34 from another application 30 on the plural target network devices 12, 14, 16 to provide information as an indication of how the qualified institutions are required to conduct business and process transactions based on the calculated set of market term estimates 15.

Table 7 illustrates other exemplary and additional details of Method 96. However, the present invention is not limited to this exemplary information and the present invention can be practiced with other exemplary information.

TABLE 7

| | | |
|---|---|---|
| Agency set up | 1. | An entity regulated by the government or an agency of the |
| and Members | | government (Agency) such as a designated Contract Market (DCM) |
| | | polls a predetermined group of Banks or other participating |
| | | institutions (Member) for purposes of establishing a term estimate. |
| | 2. | The Agency establishes a set of transparent and clear rules on |
| | | eligibility conditions for membership, membership term as well as |
| | | polling process and computation of the estimates. |
| | 3. | Member may have to demonstrate acceptable level of credit ratings |
| | | and other qualifying conditions to participate. |
| Step 1: | 1. | The Members are required to submit their estimate (e.g. interest |
| Receiving data | | rate, bonds, stock, goods or services) for the defined set of time |
| | | periods on a daily basis to the Agency. As an alternate method, the |
| | | Members may be required to submit both an estimate as well as a |
| | | notional value of a transaction (i.e. size). e.g. in the case of interest |
| | | rates, 1.5% overnight rate estimate and one million dollar size. |
| Step 2: | 1. | The Agency uses an agreed and transparent methodology to arrive |
| Term estimate | | at the term estimate for each time period. |
| calculation | 2. | This methodology could involve, but is not restricted to, the following |
| | | procedure. |

| | |
|---|---|
| a) | The polled daily estimates for each period are arranged |
| | in ascending order |
| b) | The top 20% of the polled entries and bottom 20% of |
| | the polled estimates are eliminated |
| c) | The term estimate for each period is then computed as |
| | the simple arithmetic average of the remaining entries |
| | per period. As an alternate method, the term estimate |
| | for each period may be arrived as a volume weighted |
| | average of the polled entries and its accompanying size. |

| | | |
|---|---|---|
| | 3. | This methodology may be coded in a computer readable medium for |
| | | application 30′ on server network device 20 to arrive at the set of |
| | | daily values. |
| Step 3: | 1. | The Agency publishes the term estimate from the methodology in |
| Transactions | | Step 2 to the members. These may be thought of as established |
| on established | | “equilibrium estimates” for each period. |
| estimates | 2. | Members are required to transact funds based on the above |
| | | established estimates in the following manner: |

| | |
|---|---|
| a. | Members are required to offer greater and greater amount of |
| | funds to other members at successive higher rates from the |
| | equilibrium estimates. |
| b. | Similarly, Members are required to borrow greater quantities |
| | of funds at successive rates below the equilibrium estimates |
| | from other members. The above behavior would make sense |
| | if the participating members are acting as profit maximizing |
| | economic agents. |

| | | |
|---|---|---|
| | 3. | The above 2 points in essence construct a supply-demand curve |
| | | based on the equilibrium estimates along with credible transactions |
| | | above and below the equilibrium estimate. |
| | 4. | All members are required to transact a certain amount of funds with |
| | | other members. |
| | 5. | These transactions may be done through an electronic trading |
| | | platform similar to a commodities Exchange or a Designated |
| | | Contract Market (DCM). The actual transactions based on the |
| | | above procedure will also be cleared by a regulated clearing entity |
| | | similar to a Designated Clearing Organization (DCO) under the |
| | | Commodities Futures Trading Commission (or similar national |
| | | regulatory agency) |
| Step 4: | 1. | Once backed by actual transactions around the term estimates, the |
| Data | | agency widely disseminates the data through established channels |
| dissemination | | for the wider market. |

The transactions at Steps 100, 104 and 108 may be done through an electronic trading platform similar to a commodities exchange (e.g., Chicago Board of Trade (CBOT), Chicago Mercantile Exchange (CME), etc.), stock exchange, an options exchange, a Designated Contract Market (DCM), etc. The transactions may be completed through a regulated (Security and Exchange Commission (SEC), Commodities Futures Trading Commission (CFTC), etc. or non-regulated entity. The same thing applies to equivalent steps of Method 110.

The actual transactions based on these steps can also cleared by a regulated clearing entity similar to a Designated Clearing Organization (DCO) under the CFTC or a non-regulated clearing entity.

In another embodiment, the steps of Method 96 can be practiced manually. In such an embodiment, qualified institutions can be polled manually (e.g., via telephone calls, facsimile, etc.), the calculated set of market term estimates completed with a calculator, in a spreadsheet, etc. and the results published in a non-electronic format (e.g., published in newspaper, returned by facsimile, etc.). Therefore, the present invention can be practiced directly as a new business method as well.

Electronic Market Estimation with Market Based Measures with Cloud Computing

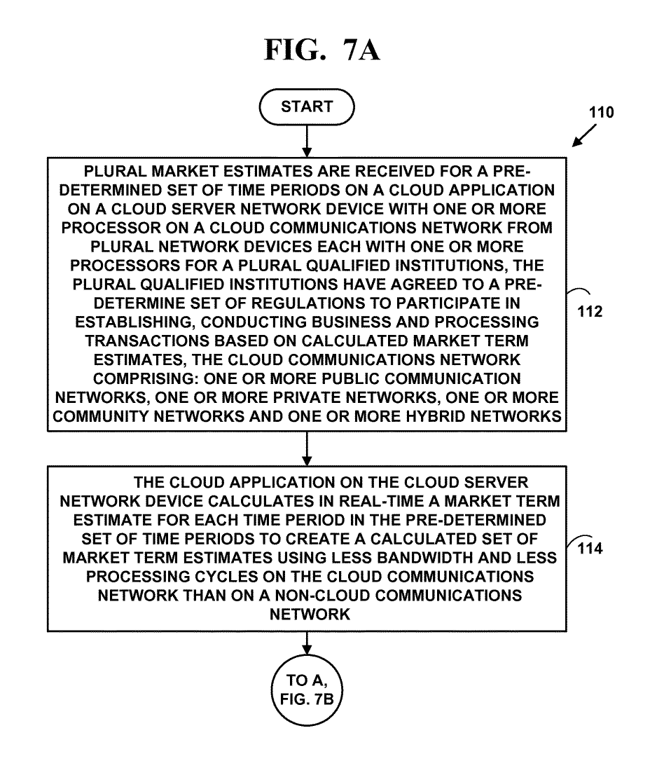

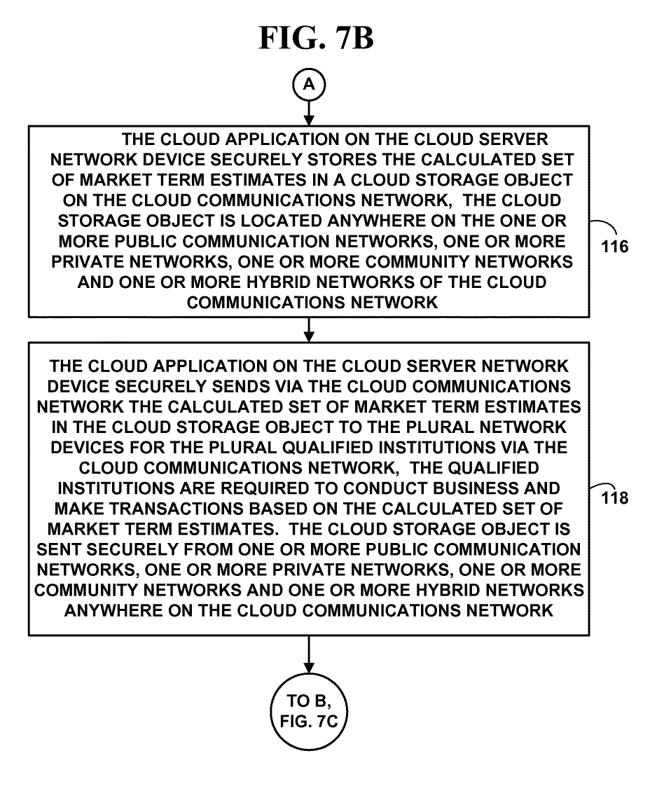

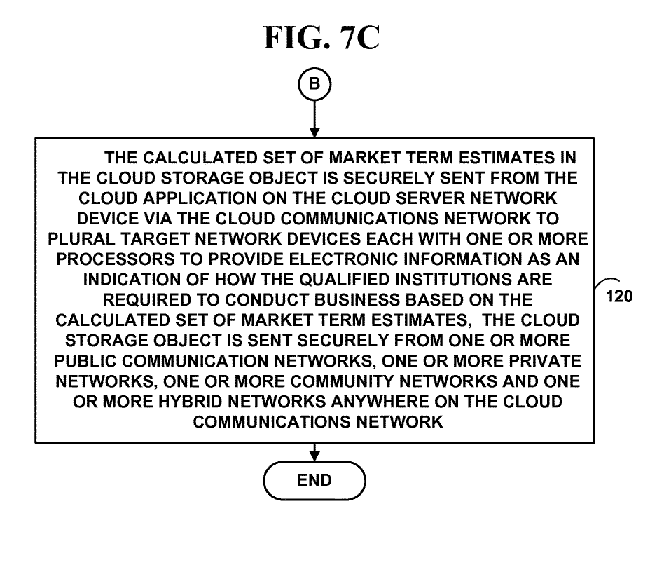

FIGS. 7A, 7B and 7C are flow diagram illustrating a Method 110 for electronic market estimation with market based measures on a cloud communications network. In FIG. 7A at Step 112, plural market estimates are received for a pre-determined set of time periods on a cloud application on a cloud server network device with one or more processor on a cloud communications network from plural network devices each with one or more processors for a plural qualified institutions. The plural qualified institutions have agreed to a pre-determined set of regulations to participate in establishing, conducting business and processing transactions based on calculated market term estimates, the cloud communications network comprising: one or more public communication networks, one or more private networks, one or more community networks and one or more hybrid networks. At Step 114, the cloud application on the cloud server network device calculates in real-time a market term estimate for each time period in the pre-determined set of time periods to create a calculated set of market term estimates using less bandwidth and less processing cycles on the cloud communications network than on a non-cloud communications network. In FIG. 7B at Step 116, the cloud application on the cloud server network device securely stores the calculated set of market term estimates in a cloud storage object on the cloud communications network. The cloud storage object is located anywhere on the one or more public communication networks, one or more private networks, one or more community networks and one or more hybrid networks of the cloud communications network. At Step 118, the cloud application on the cloud server network device securely sends via the cloud communications network the calculated set of market term estimates in the cloud storage object to the plural network devices for the plural qualified institutions via the cloud communications network. The qualified institutions are required to conduct business and make transactions based on the calculated set of market term estimates. The cloud storage object is sent securely from one or more public communication networks, one or more private networks, one or more community networks and one or more hybrid networks anywhere on the cloud communications network. In FIG. 7C at Step 120, the calculated set of market term estimates in the cloud storage object is securely sent from the cloud application on the cloud server network device via the cloud communications network to plural target network devices each with one or more processors to provide electronic information as an indication of how the qualified institutions are required to conduct business based on the calculated set of market term estimates. The cloud storage object is sent securely from one or more public communication networks, one or more private networks, one or more community networks and one or more hybrid networks anywhere on the cloud communications network.

Method 110 is illustrated with an exemplary embodiment. However, the present invention is not limited to this embodiment and other embodiments can be used to practice the invention.

In such an exemplary embodiment, In FIG. 7A at Step 112, plural market estimates 13 are received for a pre-determined set of time periods on a cloud application 30′ on a cloud server network device 20 with one or more processors on a cloud communications network 18 from plural network devices 22, 24, 26 each with one or more processors for a plural qualified institutions. The plural qualified institutions have agreed to a pre-determined set of regulations to participate in establishing, conducting business and processing transactions based on calculated market term estimates, the cloud communications network 18 comprising: one or more public communication networks 76, one or more private networks 72, one or more community networks 74 and one or more hybrid networks 78.

At Step 114, the cloud application 30′ on the cloud server network device 20 calculates in real-time a market term estimate for each time period in the pre-determined set of time periods to create a calculated set of market term estimates 15 using less bandwidth and less processing cycles on the cloud communications network 18 than on a non-cloud communications network.

In FIG. 7B at Step 116, the cloud application 30′ on the cloud server network device 20 securely stores the calculated set of market term estimates 15 in a cloud storage object 82 on the cloud communications network 18. The cloud storage object 82, and/or portions thereof is located anywhere on the one or more public communication networks 76, one or more private networks 72, one or more community networks 74 and one or more hybrid networks 78 of the cloud communications network 18. The cloud storage object 82 and/or the portions thereof is located with the cloud content location map 17 described above.

At Step 118, the cloud application 30′ on the cloud server network device 20 securely sends via the cloud communications network 18 the calculated set of market term estimates 15 in the cloud storage object 82 to the plural network devices 22, 24, 26 for the plural qualified institutions via the cloud communications network. The qualified institutions are required to conduct business and make transactions based on the calculated set of market term estimates. The cloud storage object is sent securely from one or more public communication networks 76, one or more private networks 72, one or more community networks 74 and one or more hybrid networks 78 anywhere on the cloud communications network 18.

In FIG. 7C at Step 120, the calculated set of market term estimates 15 in the cloud storage object 82 are securely sent from the cloud application 30′ on the cloud server network device 20 via the cloud communications network 18 to plural target network devices 12, 14, 16 each with one or more processors to provide electronic information as an indication of how the qualified institutions are required to conduct business based on the calculated set of market term estimates 15. The cloud storage object 82 is sent securely from one or more public communication networks 76, one or more private networks 72, one or more community networks 74 and one or more hybrid networks 78 anywhere on the cloud communications network 18.

The calculated set of market term estimates 15 are displayed from on a graphical user interface 34 from another cloud application 30 on the plural target network devices 12, 14, 16 to provide information as an indication of how the qualified institutions are required to conduct business and process transactions based on the calculated set of market term estimates 15.

The method and system describe herein provide market estimates for a set of time periods are received from plural qualified institutions that have agreed to a pre-determined set of regulations to participate in establishing, conducting business and processing transactions based on calculated market term estimates. A set of market term estimates (e.g., LIBOR, interest rates, stocks, bonds, options, other goods and services, etc.) and non-market term estimates are calculated in real-time for each time period in the set of time periods. The calculated set of market term estimates is sent to qualified institutions. The qualified institutions are required to conduct business and make transactions based on the calculated set of market term estimates. The calculated set of market term estimates is created and used on both cloud communication networks and non-cloud communications networks.

It should be understood that the architecture, programs, processes, methods and It should be understood that the architecture, programs, processes, methods and systems described herein are not related or limited to any particular type of computer or network system (hardware or software), unless indicated otherwise. Various types of general purpose or specialized computer systems may be used with or perform operations in accordance with the teachings described herein.

In view of the wide variety of embodiments to which the principles of the present invention can be applied, it should be understood that the illustrated embodiments are exemplary only, and should not be taken as limiting the scope of the present invention. For example, the steps of the flow diagrams may be taken in sequences other than those described, and more or fewer elements may be used in the block diagrams.

While various elements of the preferred embodiments have been described as being implemented in software, in other embodiments hardware or firmware implementations may alternatively be used, and vice-versa.

The claims should not be read as limited to the described order or elements unless stated to that effect. In addition, use of the term “means” in any claim is intended to invoke 35 U.S.C. §112, paragraph 6, and any claim without the word “means” is not so intended.

Therefore, all embodiments that come within the scope and spirit of the following claims and equivalents thereto are claimed as the invention.

1. A computerized, multi-step electronic loan transaction trading system, said system including:
an application server, wherein during a first electronic trading step, said application server receives first trading party data from a first trading party computerized system, said first trading party data including:
first trading party identity data; and
first trading party interest rate data for an electronic loan transaction,
wherein said application server receives second trading party data from a second trading party computerized system, said second trading party data including:
second trading party identity data; and
second trading party interest rate data for said electronic loan transaction,
wherein said application server includes a predetermined, stored computerized listing of a plurality of trading party identity data in addition to said first trading party identity data and said second trading party identity data, wherein said computerized listing represents the only trading party computerized systems from which trading party data will be accepted during said first electronic trading step and from which trading party data is required to be received during said first electronic trading step,
wherein, when said application server automatically electronically determines that:
a) said first trading party identity data matches a trading party identity data included in said predetermined, stored computerized listing,
b) said second trading party identity data matches a trading party identity data included in said predetermined, stored computerized listing, and
c) interest rate data for said electronic loan transaction has been received from all trading party computerized systems representing a trading party identity data included in said predetermined, stored computerized listing,
said application server determines an average market rate data for said electronic loan transaction representing an average market rate determined by averaging said interest rate data received from all trading party computerized systems having a trading party identity data included in said predetermined, stored computerized listing,
wherein submission of said first trading party data by said first trading party computerized system represents an irrevocable command to execute a trade in said electronic loan transaction at said average market rate once it is determined, even when said average market rate differs from said first trading party interest rate data for said electronic loan transaction;
wherein submission of said second trading party data by said second trading party computerized system represents an irrevocable command to execute a trade in said electronic loan transaction at said average market rate once it is determined, even when said average market rate differs from said second trading party interest rate data for said electronic loan transaction; and
an electronic trading platform, wherein said electronic trading platform receives from said application server:
said first trading party identity data;
said second trading party identity data; and
said average market rate data for said electronic loan transaction,
wherein said electronic trading platform automatically executes an electronic trade in said electronic loan transaction at said average market rate between said first trading party computerized system and said second trading party computerized system,
wherein, during a second electronic trading step,
said electronic trading platform transmits data representing said electronic trade and said average market rate data to a plurality of wider market computerized systems, wherein said wider market computerized systems include computerized systems in addition to said trading party computerized systems representing a trading party identity data included in said predetermined, stored computerized listing,
wherein said electronic trading platform accepts from said wider market computerized systems trade data representing revocable trading commands to execute trades in said electronic loan transaction.

2. The system of claim 1 wherein said application server includes a predetermined, stored computerized listing of a set of electronic loan transactions representing a plurality of maturities.

3. The system of claim 2 wherein said first trading party data includes first trading party interest rate data for a plurality of electronic loan transactions and said second trading party data includes second trading party interest rate data for said plurality of electronic loan transactions.

4. The system of claim 3 wherein said application server automatically electronically determines that interest rate data for said plurality of electronic loan transactions has been received from all trading party computerized systems representing a trading party identity data included in said predetermined, stored computerized listing.

5. The system of claim 4 wherein said application server determines an average market rate data for each of said plurality of electronic loan transactions representing an average market rate for each of said plurality of electronic loan transactions determined by averaging said interest rate data for each of said plurality of electronic loan transactions received from all trading party computerized systems having a trading party identity data included in said predetermined, stored computerized listing.

6. The system of claim 5 wherein submission of said first trading party data by said first trading party computerized system represents an irrevocable command to execute a trade in at least one of said plurality of said electronic loan transactions at said average market rate once it is determined, even when said average market rate differs from said first trading party interest rate data for said electronic loan transaction.

7. A computerized, multi-step electronic loan transaction trading system, said system including:
an application server, wherein during a first electronic trading step, said application server receives first trading party data from a first trading party computerized system, said first trading party data including:
first trading party identity data;
first trading party electronic loan transaction trade amount data; and
first trading party interest rate data for a electronic loan transaction,
wherein said application server receives second trading party data from a second trading party computerized system, said second trading party data including:
second trading party identity data;
second trading party electronic loan transaction trade amount data; and
second trading party interest rate data for said electronic loan transaction,
wherein said application server includes a predetermined, stored computerized listing of a plurality of trading party identity data in addition to said first trading party identity data and said second trading party identity data, wherein said computerized listing represents the only trading party computerized systems from which trading party data will be accepted during said first electronic trading step and from which trading party data is required to be received during said first electronic trading step,
wherein, when said application server automatically electronically determines that:
a) said first trading party identity data matches a trading party identity data included in said predetermined, stored computerized listing,
b) said second trading party identity data matches a trading party identity data included in said predetermined, stored computerized listing,
c) interest rate data for said electronic loan transaction has been received from all trading party computerized systems representing a trading party identity data included in said predetermined, stored computerized listing,
d) electronic loan transaction trade amount data has been received from all trading party computerized systems representing a trading party identity data included in said predetermined, stored computerized listing,
said application server determines an average market rate data for said electronic loan transaction representing an average market rate determined by calculating a weighted average based on said electronic loan transaction trade amount data and said interest rate data received from all trading party computerized systems having a trading party identity data included in said predetermined, stored computerized listing,
wherein submission of said first trading party data by said first trading party computerized system represents an irrevocable command to execute a trade in said electronic loan transaction at said average market rate once it is determined, even when said average market rate differs from said first trading party interest rate data for said electronic loan transaction;
wherein submission of said second trading party data by said second trading party computerized system represents an irrevocable command to execute a trade in said electronic loan transaction at said average market rate once it is determined, even when said average market rate differs from said second trading party interest rate data for said electronic loan transaction; and
an electronic trading platform, wherein said electronic trading platform receives from said application server:
said first trading party identity data;
said second trading party identity data; and
said average market rate data for said electronic loan transaction,
wherein said electronic trading platform automatically executes an electronic trade in said electronic loan transaction at said average market rate between said first trading party computerized system and said second trading party computerized system,
wherein, during a second electronic trading step,
said electronic trading platform transmits data representing said electronic trade and said average market rate data to a plurality of wider market computerized systems, wherein said wider market computerized systems include computerized systems in addition to said trading party computerized systems representing a trading party identity data included in said predetermined, stored computerized listing,
wherein said electronic trading platform accepts from said wider market computerized systems trade data representing revocable trading commands to execute trades in said electronic loan transaction.

8. The system of claim 7 wherein said application server includes a predetermined, stored computerized listing of a set of electronic loan transactions representing a plurality of maturities.

9. The system of claim 8 wherein said first trading party data includes first trading party interest rate data for a plurality of electronic loan transactions and said second trading party data includes second trading party interest rate data for said plurality of electronic loan transactions.

10. The system of claim 9 wherein said application server automatically electronically determines that interest rate data for said plurality of electronic loan transactions has been received from all trading party computerized systems representing a trading party identity data included in said predetermined, stored computerized listing.

11. The system of claim 10 wherein said application server determines an average market rate data for each of said plurality of electronic loan transactions representing an average market rate for each of said plurality of electronic loan transactions determined calculating a weighted average based on said electronic loan transaction trade amount data and said interest rate data for each of said plurality of electronic loan transactions received from all trading party computerized systems having a trading party identity data included in said predetermined, stored computerized listing.

12. The system of claim 11 wherein submission of said first trading party data by said first trading party computerized system represents an irrevocable command to execute a trade in at least one of said plurality of said electronic loan transactions at said average market rate once it is determined, even when said average market rate differs from said first trading party interest rate data for said electronic loan transaction.
